(19) United States
(12) Patent Application Publication
(10) Pub. No.: US 2015/0090991 A1
(43) Pub. Date: Apr. 2, 2015

(54) ELECTRO-LUMINESCENCE DEVICE AND METHOD OF MANUFACTURING THE SAME

(71) Applicant: Japan Display Inc., Tokyo (JP)

(72) Inventors: Yoshinori ISHII, Tokyo (JP); Toshihiro SATO, Tokyo (JP); Tohru SASAKI, Tokyo (JP)

(21) Appl. No.: 14/499,513

(22) Filed: Sep. 29, 2014

(30) Foreign Application Priority Data
Sep. 30, 2013 (JP) 2013-203614

(51) Int. Cl. H01L 27/32; H01L 51/56

(52) U.S. Cl. CPC H01L 27/3246; H01L 27/3251; H01L 27/322; H01L 51/56; H01L 27/3272; H01L 2251/5315; H01L 2227/323
USPC 257/40; 438/27

(57) ABSTRACT

A filling material is provided in an interval part between a first substrate provided with a light emitting device in a pixel and a second substrate provided with a color filter layer corresponding to each pixel which is provided to face each other and a protruding part is provided in the interval part. The protruding part is provided separated along one edge of each pixel. An end part in a length direction of the protruding part is formed in a cone or streamlined shape. In addition, the protruding part is formed from a material having light absorbing properties such as carbon black so as to provide light shielding properties. By adopting this structure, it is possible to solve a problem of mixing colors produced between pixels. It is possible to ensure that the flow of the filling material provided between the first substrate and the second substrate is not obstructed.

### CROSS REFERENCE TO RELATED APPLICATIONS

This application is based upon and claims the benefit of priority from the prior Japanese Patent Application No. 2013-203614, filed on Sep. 30, 2013, the entire contents of which are incorporated herein by reference.

### FIELD

An embodiment of the present invention is related to an electro-luminescence device, for example, to a useful technology applied to a top emission type electro-luminescence device.

### BACKGROUND

An in which a light emitting device holding a light emitting layer which includes an organic EL material between a pair of electrodes is provided over a substrate and emits light is being developed. There are two types of electro-luminescence device, a bottom emission type in which light emitted by an organic electro-luminescence layer (also called “organic EL layer”) is emitted from the side of a glass substrate formed with a light emitting device, and a top emission type in which light is emitted from the side opposite the glass substrate. In a bottom emission type there is a limit to an aperture ratio since elements such as transistors are formed over a lower layer side of a light emitting device. On the other hand, in a top emission type, it is easy to increase the aperture ratio of a pixel since light can be emitted in an upper direction of the light emitting device which is thought to be useful.

However, even in a top emission type, because deterioration of a light emitting device which uses an organic EL material progresses due to the effect of the water component in air, an electro-luminescence device is formed so that a light emitting device does not come into contact with air by using a sealing component.

For example, a structure in which a sealing substrate is provided via a seal material facing a first substrate formed with an organic EL layer in a matrix shape as a sealing structure of an electro-luminescence device is disclosed in Japanese Laid Open Patent Publications No. 2009-245708. In this sealing structure, the periphery of the first substrate and sealing substrate is enclosed by the seal material and a gel shaped drying agent is injected therein as a filling material so that a water component is prevented from permeating from the exterior.

In Japanese Laid Open Patent Publications No. 2010-287421, a structure is disclosed in which a first substrate including an interval layer provided so as to section one electrode of a light emitting device and a second substrate provided with a protruding layer which meshes with an aperture part of the interval layer are bonded together via a spacer arrange in a position overlapping the interval layer and thereby a filling material is maintained in a certain interval so that air bubbles do not enter or mix with the filling material is disclosed as another example of a sealing structure in this type of electro-luminescence device.

However, in an electro-luminescence device which displays an image by forming a pixel in a light emitting device which uses an organic EL layer and arranging these pixels in a matrix shape, a color filter is sometimes used in order to display color. In a top emission type electro-luminescence device, a color image is displayed by arranging a color filter in a sealing substrate which is the light emitting side. At this time, if an interval between a first substrate formed with a light emitting device and a sealing substrate formed with a color filter is wide, light emitted from the light emitting device is emitted not only from the pixel but is also emitted after passing through the color filter of an adjacent pixel leading to a mixing of colors which is a problem.

In order to prevent mixing of colors it is effective to make the interval between the first substrate and second substrate as narrow as possible. In the case of making the interval between the first substrate and second substrate narrow, if the interval is not uniform on the inner surface of the substrate, moire fringes are observed and leads to defects in external appearance. As a result, as is disclosed in Japanese Laid Open Patent Publications No. 2010-287421 for example, it is possible to maintain a constant interval while keeping the interval between the substrates narrow by arranging a spacer between the first substrate and second substrate.

However, when making the interval between the first substrate and second substrate narrow, although the amount of filling material naturally decreases, air bubbles remain within the sealing region since the fluidity of the filling material is low or a newly confirmed problem occurs whereby cavities are produced since the filling material does not spread sufficiently. In addition to low fluidity of the filling material, this problem is thought to be due to further obstruction of the fluidity of the filling material by arranging a spacer.

In addition, although a spacer includes the effect of maintaining a fixed interval between a first substrate and second substrate, as is disclosed in Japanese Laid Open Patent Publications No. 2010-287421, the problem of mixing colors produced between adjacent or close pixels cannot be solved just by simply arranging a spacer in a position overlapping an interval wall layer. That is, although a conventional spacer is effective in controlling an interval between a first substrate and second substrate, it does not contribute directly to preventing mixing colors between pixels and reversely it causes new problems such as obstruction of the dispersion of a filling material.

### SUMMARY

An electro-luminescence device according to one embodiment of the present invention includes a first substrate having a pixel region including a first electrode provided over an insulating surface, a plurality of pixels provided apart including a light emitting device provided with an organic electro-luminescence between the first electrode and a second electrode facing the first electrode, and a partition wall provided to covering an outer periphery end part of the first electrode, a second substrate provided facing the first substrate with an interval and including a color filter provided corresponding to each of the plurality of pixels and a light shielding layer provided corresponding to a region in which the plurality of pixels are separated, a filling material provided in an interval between the first substrate and the second substrate, and a protruding part provided between the first substrate and the second substrate and provided to stand within in the filling material, the protruding part is provided in a position overlapping the light shielding layer and separated along at least one edge of the pixel.

As another form of the electro-luminescence device, it is possible to form an end part in a length direction of the protruding part in a cone shape or streamlined shape. By the protruding part of this shape, the fluidity of a filling material provided between a first substrate and second substrate when then are bonded together is not obstructed.

As another form of the electro-luminescence device, it is possible to provide a protruding part with light shielding properties. For example, it is possible to provide a protruding part with light absorbing properties. In addition, as another form of the electro-luminescence device, it is possible to form the protruding part with a material having a lower refractive index than a refractive index of the filling material. By arranging this type of protruding part, it is possible to further increase a shielding function of light emitted in a diagonal direction which leaks from a pixel to an adjacent pixel.

A method of manufacturing an electro-luminescence device according to an embodiment of the present invention includes forming a first substrate provided a plurality of pixels including a light emitting device comprising a first electrode over an insulating surface, an organic electro-luminescence layer over the first electrode, and a partition layer covering a periphery edge part of the first electrode and provided over an isolation region of the plurality of pixels, forming a second substrate including a color filter layer provided corresponding to each of the plurality of pixels and a light shielding layer provided corresponding to a region in which the plurality of pixels are separated, forming a sealing pattern over a periphery part of the plurality of pixel regions in the first substrate, forming a protruding parts separately along at least one edge of the pixel at a position overlapping the light shielding layer in the second substrate, dispersing a filling material in an inner side region of the sealing pattern of the first substrate, and bonding the first substrate and second substrate facing each other under reduced pressure so that the protruding part is provided therein.

As another form of the method of manufacturing the electro-luminescence device, it is preferable to form an end part of a protruding part in a length direction in a cone shape or streamlined shape. By forming the protruding part with this type of shape, the fluidity of a filling material provided between a first substrate and second substrate when then are bonded together is not obstructed and cavity parts where the filling material is not filled are not produced.

As another form of the method of manufacturing the electro-luminescence device, it is possible to provide a protruding part with light shielding properties. For example, it is possible to provide a protruding part with light absorbing properties. In addition, as another form of the electro-luminescence device, it is possible to form the protruding part with a material having a lower refractive index than a refractive index of the filling material. By arranging this type of protruding part, it is possible to further increase a shielding function of light emitted in a diagonal direction which leaks from a pixel to an adjacent pixel.

### BRIEF DESCRIPTION OF THE DRAWINGS

FIG. 1 is a planar view diagram showing the structure of an electro-luminescence device related to one embodiment of the present invention;

FIG. 2 is a cross-sectional view diagram showing the structure of an electro-luminescence device related to one embodiment of the present invention;

FIG. 3A is a planar view diagram explaining a manufacturing step of an electro-luminescence device related to one embodiment of the present invention;

FIG. 3B is a cross-sectional view diagram explaining a manufacturing step of an electro-luminescence device related to one embodiment of the present invention;

FIG. 4A is a planar view diagram explaining a manufacturing step of an electro-luminescence device related to one embodiment of the present invention;

FIG. 4B is a cross-sectional view diagram explaining a manufacturing step of an electro-luminescence device related to one embodiment of the present invention;

FIG. 5A is a planar view diagram explaining a manufacturing step of an electro-luminescence device related to one embodiment of the present invention;

FIG. 5B is a cross-sectional view diagram explaining a manufacturing step of an electro-luminescence device related to one embodiment of the present invention;

FIG. 6A is a planar view diagram showing a structure of a pixel part of an electro-luminescence device related to one embodiment of the present invention;

FIG. 6B is a planar view diagram showing a structure of a pixel part of an electro-luminescence device related to one embodiment of the present invention;

FIG. 7 is a planar view diagram showing a structure of a pixel part of an electro-luminescence device related to one embodiment of the present invention;

FIG. 8 is a cross-sectional view diagram showing a structure of a pixel part of an electro-luminescence device related to one embodiment of the present invention;

FIG. 9 is a cross-sectional view diagram showing a structure of a pixel part of an electro-luminescence device related to one embodiment of the present invention; and

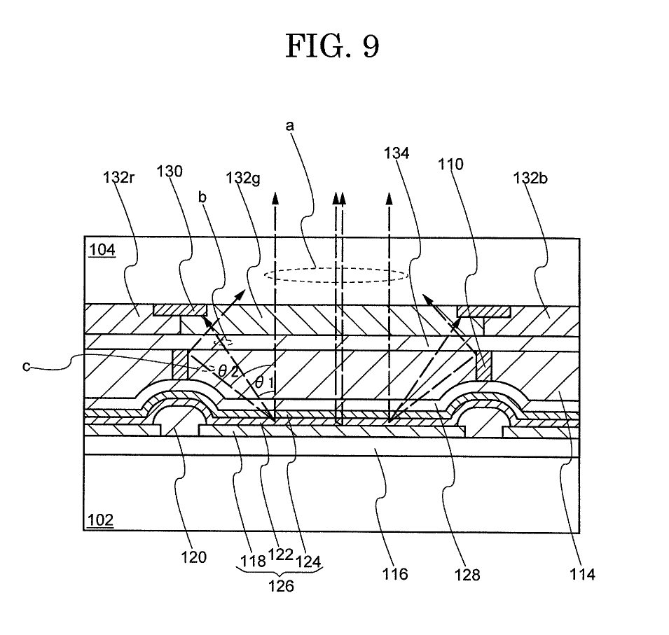

FIG. 10 is a cross-sectional view diagram showing a structure of a pixel part of an electro-luminescence device related to one embodiment of the present invention.

### DESCRIPTION OF EMBODIMENTS

The embodiments of the present invention are explained below while referring to the diagrams. However, the present invention can be realized many different forms and should not be interpreted as being limited to the detailed descriptions of the embodiments exemplified below.

Furthermore, with regards to the details of the invention explained herein, the same reference symbols are used in common across different diagrams with respect to the same parts or parts having the same functions and except for particular circumstances repeated explanations are omitted.

In the present specification, in the case where certain components or areas are present “over” or “under” and “above” or “below” other components or areas, as long as there are no particular limitations, this includes not only the case where components or areas are directly above or directly below other components or areas but also the case where components or areas are above or below other components or areas with other structural components provided in between.

### (Concept of an Electro-Luminescence Device)

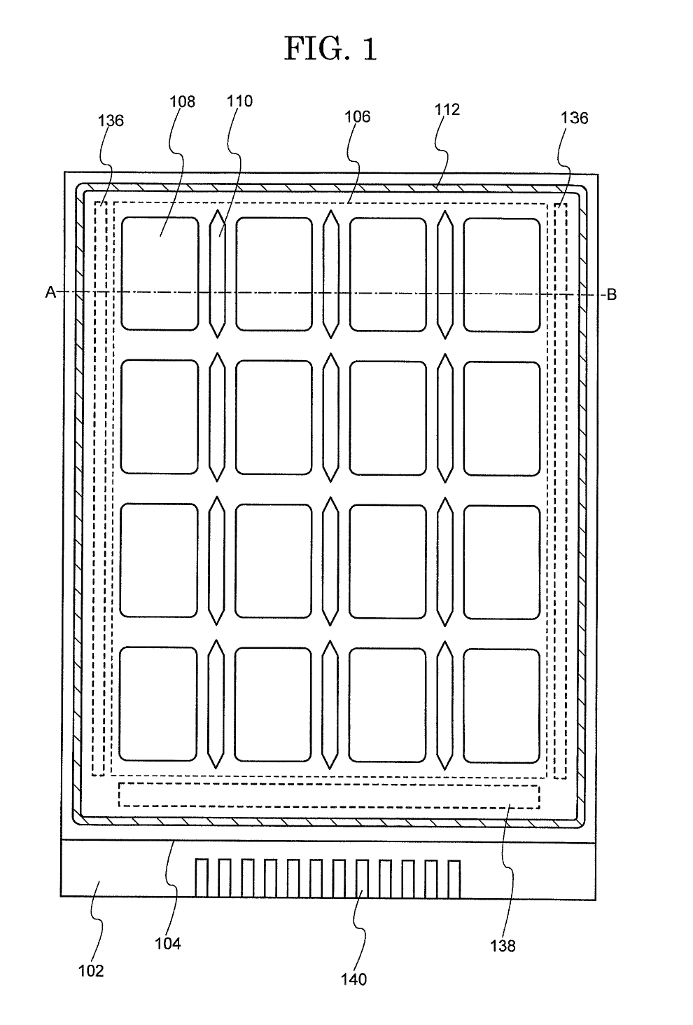

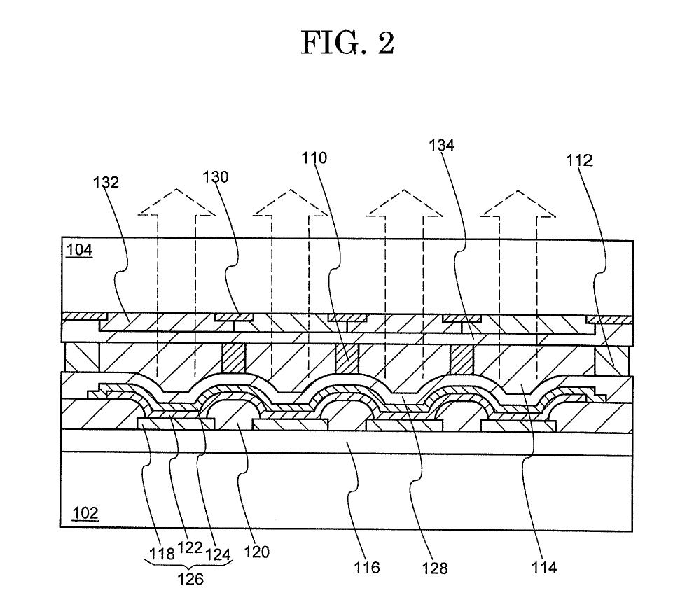

FIG. 1 shows a schematic of an electro-luminescence device related to one embodiment of the present invention and a cross-sectional structure corresponding to the line A-B shown by the dotted line in FIG. 1 is shown in FIG. 2. FIG. 1 and FIG. 2 are referred to in the explanation below related to the electro-luminescence device of the present embodiment.

An electro-luminescence device 100 includes a first substrate 102 and a second substrate 104 which are provided facing each other with a interval in between. The first substrate 102 and second substrate 104 are affixed via a seal material 112 and a filling material 114 is provided in the interval part. In the following description, the first substrate comprises a substrate provided with the devices such as a transistor (for example; thin film transistor) and the light emitting device (for example; organic electro-luminescence device), and the second substrate includes color filter and it disposed to face the first substrate.

The electro-luminescence device 100 includes a pixel region 106 provided with a plurality of pixels 108. The seal material 112 is provided so that the pixel region 106 is enclosed, and includes a single closed pattern so as to form a closed loop. The pixel 108 is formed including a light emitting device 126 provided in the first substrate 102 and a color filter layer 132 provided over the color filter 104 side corresponding to the light emitting device 126.

The light emitting device 126 is formed including a first electrode 118 provided in a surface having insulation properties (upper surface of an insulation layer 116 in FIG. 2), an organic EL layer 112 and second electrode over the first electrode 118. Although an organic EL layer 122 is formed by a single layer or stacking a plurality of layers, at least one layer is a light emitting layer including a material with light emitting properties. The light emitting device 126 in the present embodiment is formed by a first electrode 118 as a reflecting electrode and a second electrode 124 as a translucent electrode, and includes a top emission type structure in which light emitted by the organic EL layer 122 is emitted from the side of the second substrate 104.

The plurality of pixels 108 are provided separated from each other and an interval wall layer 120 is provided between the pixels. The interval wall layer 120 is provided so as to cover a periphery part of the first electrode 118. In addition, a passivation layer 128 is provided over the second electrode 128 in the first substrate 102.

The second substrate 104 includes a color filter layer 132. The color filter layer 132 is provided with different transparent light regions such as a red color filter, green color filter and blue color filter in each pixel.

The color filter layer 132 includes a pigmented layer having properties which allow light of specific wavelength bands to pass through corresponding to each color. In the case where light emitted from the light emitting device 126 is a white color, it is possible to display color by allowing the light to pass through color filters with different transparency properties corresponding to each pixel of red (R), green (G) and blue (B). In addition, in the case where the pixel 108 is provided with a light emitting device which emits light corresponding to each color red (R), green (G) and blue (B), it is possible to increase color purity of the emitted light by combining color filters corresponding to the wavelength band of that emitted light color.

In the color filter layer 132, a light shielding layer 130 is provided in a boundary region in which color filters layers with different transparency bands are adjacent. In other words, the light shielding layer 130 is provided to overlap an interval part between pixels, which is to overlap the interval wall layer 120 in the pixel region 106. Although the light shielding layer 130 is shown as being provided contacting a support substrate side of the second substrate 104 in FIG. 2, the light shielding layer 130 may also be provided over the upper layer side of the color filter layer 132.

In addition, by overlapping a plurality of color filter layers with different transparency light bands, this overlapping region demonstrates essentially the same effects as a light shielding layer because the wavelength band of transparent light becomes narrow and because transparent light intensity is attenuated due to the pigmented layer. Therefore, instead of the light shielding layer 130, it is possible to apply a structure in which a plurality of color filter layers within different transparent light bands and treat this as a light shielding layer.

Although at least the color filter layer 132 is provided in the second substrate 104, an overcoat layer 143 may also be provided so as to cover the color filter layer 132. The overcoat layer 134 protects the color filter layer 132 and includes a function of planarizing a surface.

A protruding part 110 is provided between the first substrate 102 and the second substrate 104. The protruding part 110 is provided to stand independently inside the filling material 114. The protruding part 110 is provided between pixels, that is, in a region overlapping the light shielding layer 130. Although the protruding part 110 is provided along at least one edge of a pixel 108, the protruding part is divided narrowly in pixel units. In FIG. 1, the protruding part 110 is shown provided along one edge in a length direction of a pixel 108. In addition, an end part in a length direction of the protruding part 110 includes a cone shape so that it becomes narrower towards a tip end part.

By arranging the protruding part 110 between the first substrate 102 and the second substrate 104, the protruding part includes a function as a spacer which maintains a fixed interval between the substrates. By arranging the protruding part 110 between pixels which is a region overlapping the light shielding layer 130, it is possible to effectively use the protruding part as a spacer without decreasing an aperture ratio of the pixel 108 or pixel region 106.

An insulation layer 116 includes a surface with insulation properties in a surface contacting the first electrode 118. The insulation layer 116 includes a single insulation layer or a plurality of stacked insulation layers 116. In the case where the insulation layer 116 has a stacked layer structure, a thin film transistor may be buried therein. In addition, a terminal part which inputs a signal may be provided over end part of the first substrate 102 and a circuit which controls emitted light of the light emitting device 126 in the pixel 108 using a thin film transistor may also be provided.

FIG. 1 shows a form in which a scanning line drive circuit 136 and data line drive circuit are provided adjacent to the pixel region 106 in the case where a pixel circuit is formed by a thin film transistor in the pixel region 106. A thin film transistor which forms the scanning line drive circuit 136 and data line drive circuit 138 can be provided so as to be buried within the insulation layer 116 the same as the thin film transistor provided in a pixel 108. In the present embodiment, the scanning line drive circuit 136 and data line drive circuit 138 etc. are ancillary structural components and are not absolutely essential elements.

### (Manufacturing Method of an Electro-Luminescence Device)

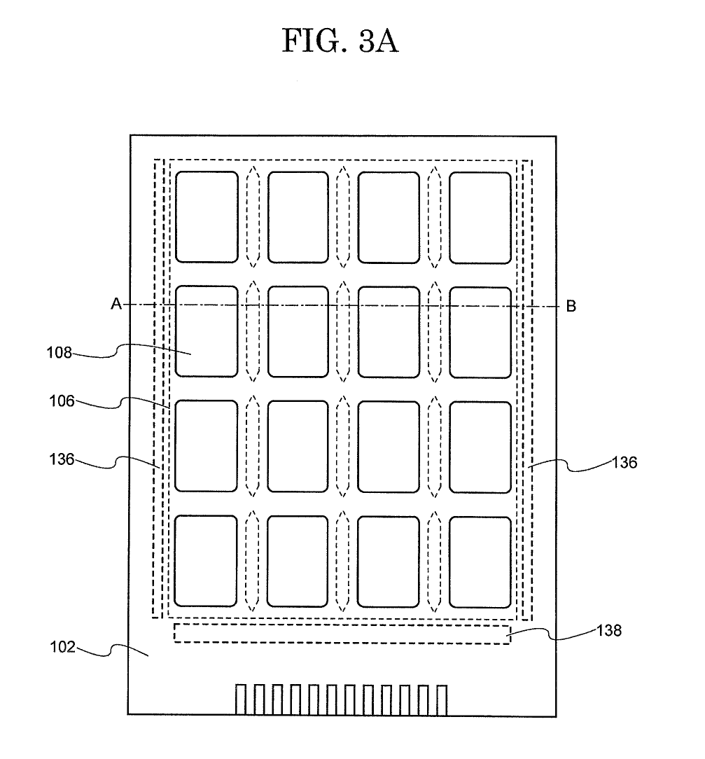

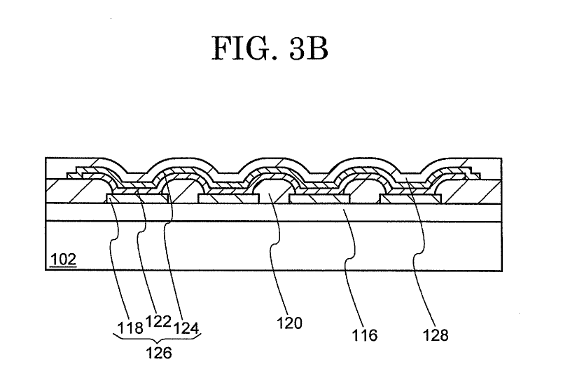

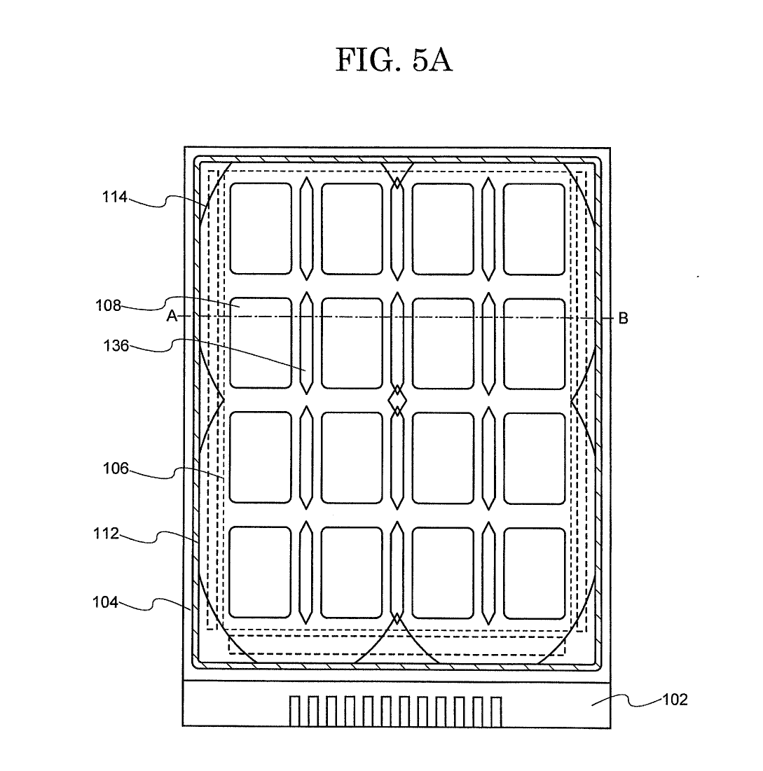

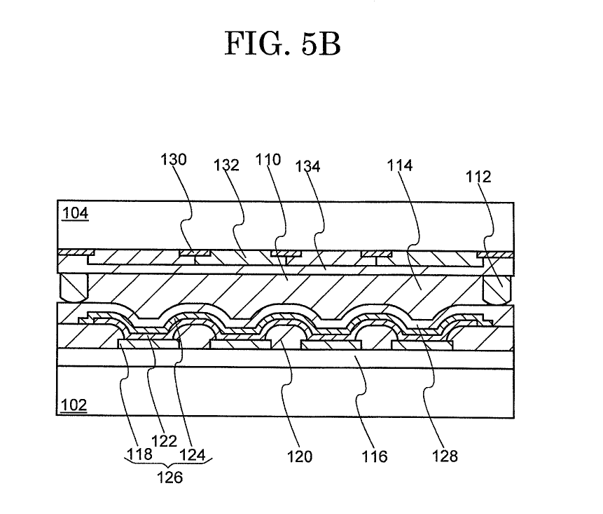

Among the manufacturing steps of the electro-luminescence device 100, a step for bonding a first substrate and second substrate is explained while referring to FIG. 3A, FIG. 3B, FIG. 5A and FIG. 5B.

The outline of manufacturing step of the first substrate 102 is explained referring to FIG. 3A and FIG. 3B. FIG. 3A is a planar view diagram of the first substrate and FIG. 3B shows a cross-sectional view corresponding to the line A-B shown by the dashed line in the planar view of FIG. 3A.

A plurality of first electrodes 118 are formed over the insulation layer 116 as one step in forming the first substrate 102. The first electrode 118 is formed so that it is provided having a certain interval. In addition, the interval wall layer is formed so as to cover a periphery edge part of the first electrode 118. The interval wall layer 120 is formed using a material having insulation properties and is preferred to be formed to have a smooth curved surface shape from a lower end part which contacts with the first electrode 118 to an upper end corner part.

An organic EL layer 122 is formed over an upper layer of the first electrode 118. A second electrode 124 is formed over the organic EL layer 122. A region in which the organic EL layer 122 and the second electrode 124 overlap serves as the light emitting device 126. The organic EL layer 122 is formed to a thickness of about 100 nm to 300 nm. Even if the organic EL layer 122 is formed to this thickness, by forming in advance the interval wall layer 120 so that it has a smooth curved surface shape as described above, it is possible to uniformly and continuously form the organic EL layer 122 in a surface of the interval wall layer 120 from the first electrode 118.

By forming the organic EL layer 122 and second electrode 124 across the entire surface while a plurality of the first electrodes 118 is formed separated, the light emitting device 126 is formed simultaneously in each pixel. Since the second electrode 124 in the light emitting device 126 is provided with a common potential in each of the pixels 108 respectively, the second electrode is formed continuously across a plurality of pixels.

Since deterioration of the organic EL layer 122 progresses due to a water component, it is preferred to form a passivation layer 128 over the second electrode 124. The passivation layer 128 is preferred to be formed using a translucent insulation film such as a silicon nitride film or silicon oxide film.

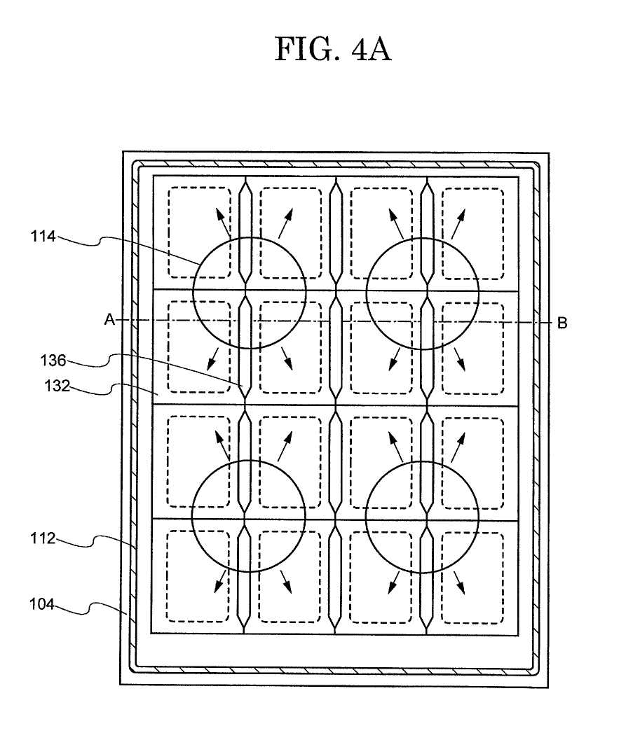

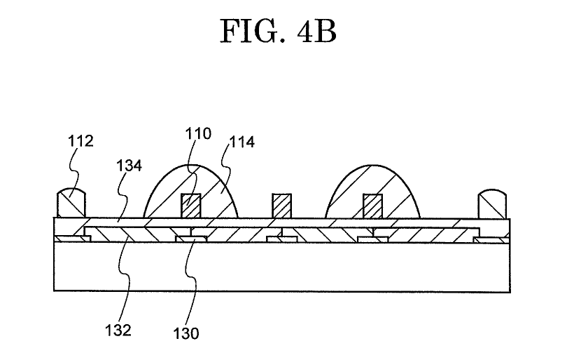

Next, a manufacturing step of the second substrate 104 is explained referring to FIG. 4A and FIG. 4B. FIG. 4A is a planar view diagram of the second substrate and FIG. 4B shows a cross-sectional view corresponding to the line A-B shown by the dotted line in the planar view in FIG. 4A.

A light shielding layer 130 is formed in the second substrate 104. The light shielding layer 130 is formed using a metal film with a comparatively low reflection ratio such as chrome (Cr), titanium (Ti) or tantalum (Ta). Alternatively, the layer may also be formed using a resin material including a black pigment such as carbon black etc. The color filter layer 132 is formed corresponding to each pixel in which a pigment layer corresponding to red (R), green (G) and blue (B) etc. is provided in the first substrate 102.

In the color filter layer 132, the shielding layer 130 is provided so as to overlap a boundary region of a pigment layer of different colors. That is, by arranging the light shielding layer 130 so as to section each pixel, because dispersion of the light emitted from the light emitting device in a horizontal direction is somewhat restricted, a constant function appears with respect to prevention of mixing colors between pixels.

The overcoat layer 134 is formed over the color filter layer 132. The overcoat layer 134 is formed using an organic resin composition with translucent properties by acryl etc. The overcoat layer 134 protects the color filter layer 132 as also functions to planarize a surface of the second substrate 104.

The protruding part 110 is formed over the overcoat layer 134. The protruding part 110 is formed in a position overlapping the light shielding layer 130. After the organic resin composition with light curing properties is coated over the overcoat layer 134 and exposed using a mask, the protruding part 110 is formed with certain form in a position overlapping the light shielding layer 130 as is shown in FIG. 4A.

The form of the protruding part 110 is not formed in a single line shape in a pixel region but is separated into a plurality corresponding to the arrangement of pixels and is preferred to be formed for example in a broken line shape to be adjacent to each pixel. That is, it is preferred that the protruding part be formed narrowly in pixel units and provided with equal intervals corresponding to the interval at which the pixels are provided. In addition, an end part in a length direction of the protruding part is formed in a cone shape or streamlined shape so as to become thinner towards the tip end. By forming the protruding part with this form, the fluidity of a filling material is not obstructed when coating the filling material.

In addition, the protruding part 110 includes a function of a spacer maintaining a constant interval between the first substrate 102 and the second substrate 104 when the substrates are bonded together. As a result, the height of the protruding part 110 is preferred to be the same as the interval between the first substrate 102 and the second substrate 104.

A sealing material 112 is formed over the overcoat layer 134. The sealing material 112 is formed in a closed loop pattern so as to enclose the pixel region 106 formed in the first substrate 102 when the second substrate 104 and first substrate 102 are bonded together. Although an organic resin composition having adhesion properties which is a light curing property is preferred to be used for the sealing agent 112, instead of this, an organic resin composition with thermosetting properties may also be used. In either case, the sealing material 112 is supported in an uncured state and is not completely cured at a drawing stage.

The sealing material 112 is coated so as to provide a loop shape with no aperture part using a dispenser. For example, it is preferred that the sealing material 112 is formed using a UV curable resin in a nitrogen atmosphere when coated using a dispenser. A filling material 114 is dripped or coated in an inner side region of the sealing material 112 formed in a loop shape. The filling material 114 is dripped at a necessary amount so that it is filled without cavities in an interval part between the first substrate 102 and color substrate 102 when they bonded together with the interval between them.

It is possible to use a resin material such as an epoxy group material or acryl group material for the filling material 114. For example, it is possible to use a resin material added with a gel shaped drying agent for example. Because the filling material 114 applied with this type of organic resin composition has a comparatively high viscosity, it is preferred that it be dripped in several places of the second substrate 104. When the filling material 114 is dripped or coated over the second substrate 104, after the first substrate 102 and second substrate 104 are sealed, it is preferred that dripping or coating is performed in a nitrogen atmosphere so that air with moisture does not remain.

Although the second substrate 104 coated with the filling material 114 is held in a nitrogen atmosphere, next this atmosphere is reduced in pressure and an air bubbles included in the filling material 114 are removed. At this time, any solvent included in the filling material 114 is also removed by placing the filling material 114 under a reduced pressure.

FIG. 5A and FIG. 5B show a step of bonding the first substrate 12 and second substrate 104 manufactured in this way. Bonding of the first substrate 12 and second substrate 104 is performed under a reduced pressure. In this case, because the filling material 114 has high viscosity and low fluidity, cavity parts which do not fill the interval part between the first substrate 12 and second substrate 104 sometimes remain.

However, when the first substrate 12 and second substrate 104 are returned to the atmosphere from a reduced pressure in a bonded state, the first substrate 102 and second substrate 104 is pushed by the atmosphere. Because of this, internal cavities disappear as is shown in FIG. 2 and it is possible to fill the filling material 114 between the first substrate 102 and second substrate 104. In addition, the sealing material 102 is cured in this state and the first substrate 102 and second substrate 104 are fixed together.

In this case, even if the first substrate 102 and second substrate 104 are pushed by the atmosphere, because the protruding part 110 acts as a spacer, it is possible to maintain a constant interval between the substrates in the pixel region 106. That is, because it is possible to maintain a constant interval in a periphery edge part and center part in the pixel region 106, it is possible to ensure that no gap irregularities are produced.

Furthermore, by providing the protruding part 110 with a shape so that fluidity of the filling material 114 is not obstructed, it is possible to ensure that no air bubbles or cavity parts remain in the interval between the first substrate 102 and second substrate 104 when the substrates are bonded.

In this way, by arranging a protruding part 110 corresponding to a pixel 108, it is possible to bond the first substrate 102 and second substrate 104 while maintaining a constant between the substrates. In addition, when arranging the protruding part 110 along a periphery part of a pixel 108, it is possible to ensure that cavity parts in which the filling material does not spread are not produced by providing a release end so that flow of the filling material is not obstructed.

### (Structure of a Pixel Region)

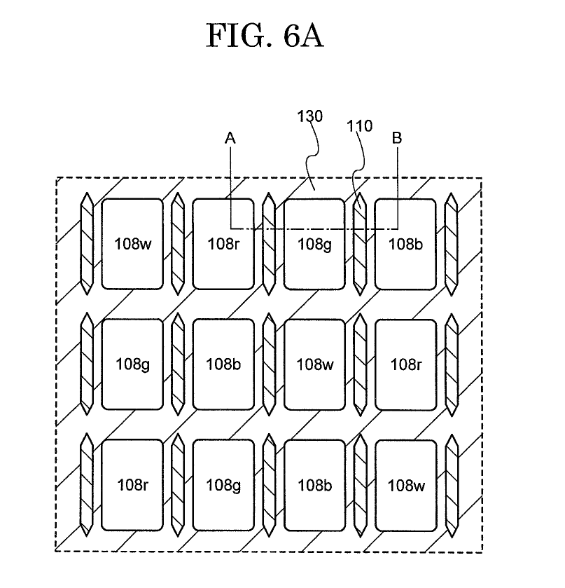

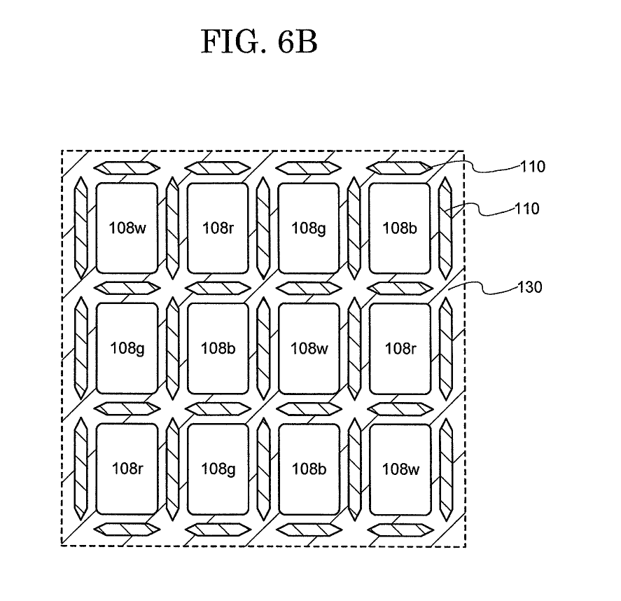

FIG. 6A and FIG. 6B show the form of the pixel region 106 seen from the side of the second substrate 104. FIG. 6A shows an example of the pixel region 106 in which pixels 106 (R pixel 108r, G pixel 108g, B pixel 108b) of each color red (R), green (G), blue (B) are provided diagonally.

Although each pixel is provided near each other, for example pixel 108g and pixel 108r are provided with an interval so that they are respectively separated. In addition, the light shielding layer 130 is provided so as to cover the interval between pixels provided separately. The protruding part 110 is provided along one edge of a pixel 108 in a region in which the light shielding layer 130 is provided.

The shape of the protruding part 110 is formed in a cone shape so that the end part in a length direction becomes thinner towards the tip end. This is to ensure that fluidity of the filling material is not obstructed when provided the protruding part to stand independently within the filling material. As a result, the form of the protruding part 110 may have a tip end part in a streamlined shape so that fluid resistance decreases.

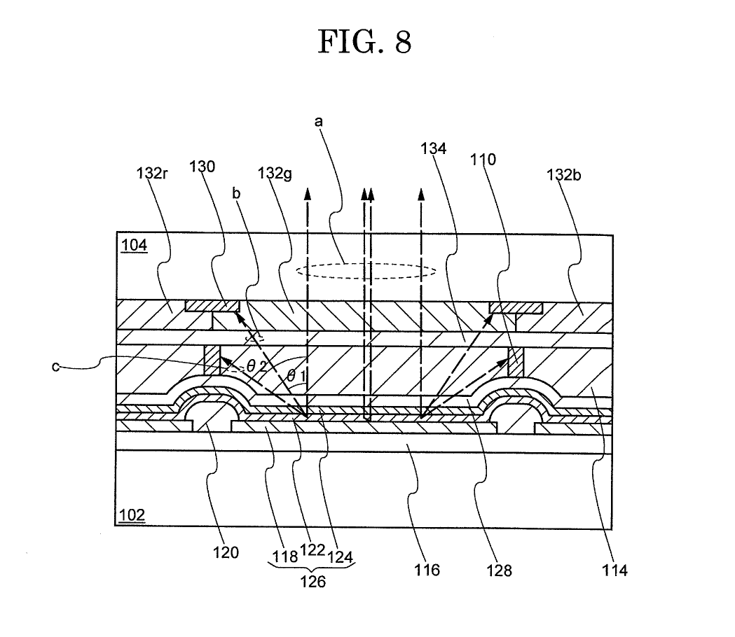

In addition to the shape of the protruding part 110, the arrangement of the protruding part 110 is preferred to be divided into a plurality corresponding to a pixel 108 as is shown in FIG. 8, and is aligned in rows so that the length direction is provided in a single direction between each pixel respectively. By aligning in rows in this way, when the filling material is dripped or coated and the first substrate and second substrate are bonded, it is possible to ensure that the flow of the filling material is not obstructed.

The light shielding layer 130 includes a function for shielding light so that light emitted from a certain pixel does not leak to an adjacent pixel so that colors are not mixed between adjacent pixels. In this case, by applying a structure in which the protruding part 110 which overlaps the light shielding layer 130 includes light shielding properties, it is possible to further increase the light shielding effects.

In the case where the protruding part 110 is provided with light shielding properties, by arranging not simply a column shape but so that a side surface is formed along at least one edge of a pixel, it is possible to prevent mixing of colors between for example pixel 108g and adjacent pixels 108r and 108b.

Furthermore, although the protruding part 110 is shown provided along one edge of a pixel in FIG. 6A, as long as the fluidity of the filling material 114 is not obstructed, a different arrangement to that shown in FIG. 6A is also possible. For example, as is shown in FIG. 6B, the protruding part 110 may be provided so as to enclose the periphery of a pixel 108. In this case, the protruding part 110 does not completely enclose the entire periphery of a pixel 108, but is preferred to have a release end on at least one part so that the flow of the filling material is not obstructed.

In FIG. 6B, because the area enclosing a pixel 108 increases when the protruding part 110 is formed by a component with light shielding properties, it is possible to further reduce mixing of colors being generated between pixels.

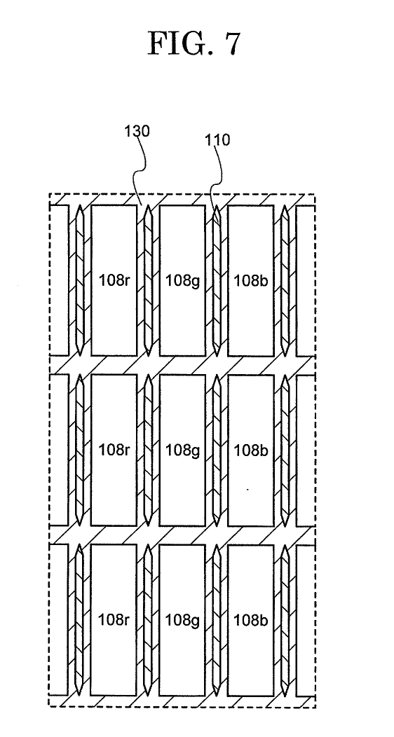

FIG. 7 shows the form of the pixel region 106 when a color filter layer of each color pixel (R pixel 108r, G pixel 108g, B pixel 108b) is provided in a stripe shape. In this case, because a color filter layer of the same color is provided in the same row direction, the protruding part 110 is provided along a pixel of each color respectively and thereby it is possible to overcome the problem of mixing colors between pixels.

In FIG. 6A, FIG. 6B and FIG. 7, a white color pixel may also be included within the pixel region 106. Even in the case where a white color pixel 108w is included, because it is possible that the problem of mixing colors between pixels may be generated, by arranging the protruding part 110 it is possible to further increase contrast while reducing the effects of mixing colors.

In this way, as well as arranging the protruding part 110 along a periphery part of a pixel, by providing a release part so that the flow of the filling material is not obstructed, it is possible to further increase the function of shielding light emitted diagonally which leaks from a pixel to an adjacent pixel.

Furthermore, although not shown in the diagram, it is possible to similarly apply the protruding part 110 in a pixel with a delta arrangement or “Pentile” arrangement. Because the form of the electro-luminescence device related to the present embodiment which is provided with a protruding part between pixels can be applied regardless of the arrangement of the pixels, with regards to the details of a pixel explained below, other arrangements which can be applied are also explained including the pixel region having the arrangement described above.

FIG. 8 shows a cross-sectional diagram corresponding to the line A-B shown by the dotted line in FIG. 6A. The pixel region 106 is provided so that the first substrate 102 formed with the light emitted device 126 and the second substrate 104 provided with the color filter layer 132 are facing each other with an interval in between. The filling material 114 is provided in an interval part between the first substrate 102 and the second substrate 104. The filling material 114 adhere the first substrate 102 and the second substrate 104 and is also provided to seal the light emitting device 126.

The light emitting device 126 is formed in a region in which the first electrode 118, organic EL layer 122 and second electrode 124 overlap. The light emitting device 126 includes a function whereby either the first electrode 118 or second electrode 124 becomes an anode (electrode over the side where holes are injected) and the other becomes a cathode (electrode over the side where electrons are injected). Although the anode and cathode are formed from each type of conductive material, usually the anode is formed with a material with a higher work function with respect to the cathode.

Since the electro-luminescence device shown in the present embodiment is a top emission type in which light is emitted from the side of the second substrate 104, the first electrode 118 serves as a reflection electrode. It is preferred that a metal material such as titanium (Ti), titanium nitride (TiN), platinum (Pt), nickel (Ni), chrome (Cr) or tungsten (W) for example is applied for making the first electrode 118 into an anode. Because these metals have a low reflective index compared to aluminum (Al) or silver (Ag), it is preferred to arrange an indium tin oxide (ITO) film with a high work function on the side contacting the organic EL layer 122 and a multilayer structure provided with an aluminum (Al) or silver (Ag) layer which serves as a light reflecting surface on a lower layer side as a structure for further increasing a reflective index as a reflection electrode.

The second electrode 124 includes translucency and in order to make the second electrode 124 a cathode, it is preferable to use for example, calcium (Ca) or magnesium to aluminum or a material containing an alkali metal such as lithium (Li) and form the electrode thin. Furthermore, a transparent conductive film such an indium tin oxide (ITO) or indium tin zinc oxide (IZO) may be stacked thereupon.

On the other hand, in order to make the first electrode 118 a cathode, a metal material such as aluminum or silver (Ag) may be used as described above. In addition, in order to make the second electrode 124 an anode, a transparent conductive film such an indium tin oxide (ITO) or indium tin zinc oxide (IZO) may be used.

The organic EL layer 122 may be formed using either a low molecular or high molecular organic material. For example, in the case where a low molecular organic material is used, in addition to a light emitting layer including an organic material having light emitting properties, the organic EL layer 122 is formed including a hole transport layer or an electron transport layer so as sandwich the light emitting layer. In the light emitting device 120, in order to emit white light, a structure may be adopted whereby a light emitting layer or light emitting element which emits light of each color red (R), green (G) and blue (B) are stacked or a structure whereby a light emitting layer or light emitting element which emit blue (B) and yellow (Y) light are stacked.

The color filter layer 132 of the second substrate 104 includes a plurality of layers having different transparent light wavelength bands corresponding to each color of a pixel (for example, as is shown in FIG. 8, red (R) color filter layer 126r, green (G) color filter layer 126g and blue (B) color filter layer 126b). The color filter layer 132 is formed to a thickness of about 3 μm from an organic resin material including a pigment or dye. The light shielding layer 130 is provided to overlap a boundary region in a part where color filter layers of different colors are adjacent. The light shielding layer 130 is formed to thickness so that light does not pass through using a metal such as chrome (Cr), titanium (Ti) or tantalum (Ta).

The overcoat layer 134 formed from an organic resin material having translucency such as acryl is provided over the color filter layer 132. Light generated in the organic EL layer 122 of the light emitting device 126 is emitted in all 4π directions when expressed as a solid angle. Among the components of this emitted light, light which is emitted in a roughly perpendicular direction towards the second substrate 104 and light reflected by the first electrode 118 and emitted in a direction towards the second substrate 104 are utilized as emitted light of that substrate (light component of the path as shown in the diagram).

On the other hand, among the light emitted in a diagonal direction from the organic EL layer 122, light emitted diagonally in a shallow angle using a perpendicular direction as a reference (emitted light component shown by θ1 in FIG. 8) is shielded by the light shielding layer 130 (light component of the path b shown in the diagram). In addition, among the light emitted in a diagonal direction, light emitted diagonally at a large angle with respect to a perpendicular direction (emitted light component shown by θ1 in FIG. 8) is not shielded by the light shielding layer 130 but is light which leaks to an adjacent pixel (light component of the path c shown in the diagram).

However, because the structure of a pixel shown in the present embodiment is provided with a protruding part in a region which overlaps the slight shielding layer 130, it is possible to shield light from leaking to an adjacent pixel 108. For example, when the protruding part 110 is formed from a material having translucency including a pigment such as carbon black, it is possible to absorb light emitted in this diagonal direction using the protruding part 110. In the case where the protruding part 110 is provided with light absorbing properties, when these characteristics are expressed by an attenuation rate of incidence light, it is preferred to provide a value of 1 or more and preferably 2 or more as an optical density (OD value). By providing the protruding part 110 with such characteristics, it is possible to attenuate the light emitted in a diagonal direction to an extent whereby light is not emitted to an adjacent pixel and mixing colors does not occur. In addition, a thin film such as chrome (Cr), titanium (Ti) and tantalum (Ta) with a low reflective index may be formed over a surface of the protruding part 110 to provide light shielding properties.

As another preferred form, light emitted in a diagonal direction from the organic EL layer 122 may be reflected by the protruding part 110. For example, by reducing a refractive index of the protruding part 110 with respect to the refractive index of the filling material 114, it is possible to reflect light incident to all reflective corners amount the light incident from a diagonal direction using the protruding part 110. Alternatively, a metal cover film with a high reflective index such as aluminum (Al) or silver (Ag) may be formed over a surface of the protruding part 110 so that light emitted in a diagonal direction is reflected. Alternatively, the surface of a metal cover film may be provided with a matt shape so that light is scattered. Even when this type of protruding part 110 is provided with light reflecting properties, it is possible to prevent light from leaking to an adjacent pixel and control a drop in image quality due to mixing colors.

As described above, according to the electro-luminescence device shown in the present embodiment, a protruding part provided so as to overlap a light shielding layer includes a function as a spacer for maintaining a constant interval between a first substrate and a second substrate and can also shield light emitted in a diagonal direction from a pixel being emitted to an adjacent pixel. That is, by arranging a protruding part which stands independently within a filling material adjacent to a pixel, it is possible to control a drop in image quality due to mixing colors produced between adjacent or pixels in close vicinity.

### Modified Example

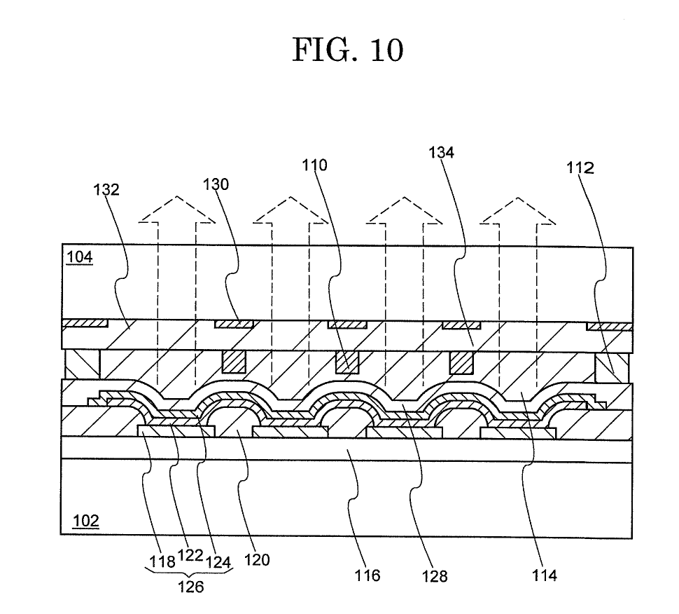

As is shown in FIG. 10, the protruding part 110 is not required to be in contact with bot structured bodies (for example, overcoat layer 134, passivation layer 128) formed in the second substrate 104 and first substrate 102 but may be provided to contact either one.

In FIG. 10, a structure is shown wherein the protruding part 110 is provided in contact with the overcoat layer 134 of the second substrate 104 and not directly connected with the first substrate 102. By adopting such as a structure, it is possible to prevent mixing colors produced between pixels as described above. In addition, because the protruding part 110 acts as an obstacle, it is possible to prevent a gap interval from contracting more than the height of the protruding part 110.

In addition, in the case of an electro-luminescence device in which a substrate part of the first substrate 102 and second substrate 104 is formed from a flexible material and can bend, it is possible to secure the flexibility by making one end of the protruding part 110 a free end.

What is claimed is:

1. An electro-luminescence device comprising:
a first substrate having a pixel region including a first electrode provided over an insulating surface, a plurality of pixels provided apart including a light emitting device provided with an organic electro-luminescence between the first electrode and a second electrode facing the first electrode, and a partition wall provided to covering an outer periphery end part of the first electrode;
a second substrate provided facing the first substrate with an interval and including a color filter provided corresponding to each of the plurality of pixels and a light shielding layer provided corresponding to a region in which the plurality of pixels are separated;
a filling material provided in an interval between the first substrate and the second substrate;
a protruding part provided between the first substrate and the second substrate and provided to stand within in the filling material, and
the protruding part being provided in a position overlapping the light shielding layer and separated along at least one edge of the pixel.

2. The electro-luminescence device according to claim 1 wherein an end part in a length direction of the protruding part is a cone shape.

3. The electro-luminescence device according to claim 1 wherein an end part in a length direction of the protruding part is streamlined.

4. The electro-luminescence device according to claim 1 wherein the protruding part includes light absorption properties.

5. The electro-luminescence device according to claim 1 wherein a refractive index of the protruding part is smaller than a refractive index of the filling material.

6. The electro-luminescence device according to claim 1 wherein the protruding part is provided along an outer periphery part of the pixel and also includes an aperture part so that the flow of the filling material is not obstructed.

7. A method of manufacturing an electro-luminescence device comprising:
forming a first substrate provided a plurality of pixels including a light emitting device comprising a first electrode over an insulating surface, an organic electro-luminescence layer over the first electrode, and a partition layer covering a periphery edge part of the first electrode and provided over an isolation region of the plurality of pixels
forming a second substrate including a color filter layer provided corresponding to each of the plurality of pixels and a light shielding layer provided corresponding to a region in which the plurality of pixels are separated;
forming a sealing pattern over a periphery part of the plurality of pixel regions in the first substrate;
forming a protruding parts separately along at least one edge of the pixel at a position overlapping the light shielding layer in the second substrate;
dispersing a filling material in an inner side region of the sealing pattern of the first substrate; and
bonding the first substrate and second substrate facing each other under reduced pressure so that the protruding part is provided therein.

8. The method of manufacturing an electro-luminescence device according to claim 7 wherein an end part in a length direction of the protruding part is formed in a cone shape.

9. The method of manufacturing an electro-luminescence device according to claim 7 wherein an end part in a length direction of the protruding part is formed in a streamline shape.

10. The method of manufacturing an electro-luminescence device according to claim 7 wherein the protruding part is formed from a light absorbent material.

11. The method of manufacturing an electro-luminescence device according to claim 7 wherein the protruding part is formed from a light material having a lower refractive index than the filler.

12. The method of manufacturing an electro-luminescence device according to claim 7 wherein the protruding part is provided along the outer periphery of the pixel and is formed to include a release end so that the fluidity of the filling material is not obstructed.
